(19) United States
(12) Patent Application Publication
(10) Pub. No.: US 2006/0022342 A1
(43) Pub. Date: Feb. 2, 2006

(54) Semiconductor device and method for manufacturing the same

(75) Inventors: Kazuhiko Fukutani, Santa Cruz, CA (US); Tohru Den, Tokyo (JP); Hirokatsu Miyata, Hadano-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/986,939

(22) Filed: Nov. 15, 2004

Related U.S. Application Data
(63) Continuation-in-part of application No. 10/271,472, filed on Oct. 15, 2002, now Pat. No. 6,852,431.

(30) Foreign Application Priority Data
Oct. 16, 2001 (JP) 2001-317682

(51) Int. Cl. H01L 23/52

(52) U.S. Cl. 257/758

(57) ABSTRACT

A semiconductor device has multi-layered interlayer insulating layers 3 formed on a semiconductor substrate 1, and wirings 4 formed in the interlayer insulating layers 3. The interlayer insulating layers 3 are composed of porous bodies having fine columnar pores and parent-material regions consisting mainly of silicon oxides surrounding the fine pores. The wirings 4 are composed of structures wherein columnar substances containing aluminum are dispersed in a base material containing silicon, or regions wherein an electrically conductive material is introduced in a portion of the porous bodies. The average diameter of the fine pores in the porous bodies is 1 nm or larger and 10 nm or smaller, and the average distance between the fine pores is 3 nm or larger and 15 nm or smaller. The fine pores in the porous bodies is formed perpendicularly, or substantially perpendicularly to the film surface on a semiconductor substrate 1.

This is a continuation-in-part application of U.S. patent application Ser. No. 10/271,472 filed on Oct. 15, 2002.

### BACKGROUND OF THE INVENTION

1. Field of the Invention

The present invention relates to a semiconductor device having a novel structure and a method for manufacturing the same; and more specifically to a semiconductor device having multi-layer wirings of a lowered wiring capacity by the use of a low-dielectric-constant film of a novel structure, and a method for manufacturing the same.

2. Related Background Art

With the miniaturization of semiconductor devices in recent years, wiring capacity has increased, and the delay of signals through wirings has become significant. For lowering wiring capacity, the reduction of the resistance of metal wiring, and the use of materials having a low specific dielectric constant as interlayer insulating films can be considered. In general, as a method for reducing the resistance of metal wiring, the change of the metal for wirings from aluminum to copper, which has a lower resistivity, is considered.

On the other hand, in order to lower the specific dielectric constant of the interlayer insulating films, instead of conventional SiO₂ (specific dielectric constant ε=4.3) the use of Si—O-based inorganic materials having a low specific dielectric constant, such as fluorine-doped SiOF and HSQ (hydrogen silsesquioxane), organic materials, such as a polyimide-based resin, the mixtures of organic and inorganic materials and the like have been studied.

As a method for lowering the specific dielectric constant of interlayer insulating films, making the above substances or the like porous is also examined. Japanese Patent Application Laid-Open No. 2000-216153 discloses a porous film consisting of an organic-inorganic composite film formed by a plasma CVD method using a mixed gas of a silicon alkoxide and an organic compound. Japanese Patent Application Laid-Open No. 2002-75982 discloses a porous-silica-based film consisting of polyalkylsilazane and polyacrylic acid or the like.

According to these patent gazettes, a low-dielectric-constant material can be formed by making the material porous.

However, since the film quality of porous bodies composed of organic materials or the mixture of organic and inorganic materials is significantly different from the film quality of a silicon oxide film or the like used as the material of interlayer insulating films in conventional semiconductor devices, various new processes are required leading to the rise of costs for manufacturing the semiconductor devices. In addition, there are many materials inferior to conventionally used silicon oxide or the like in the resistance to the semiconductor process and the stability for a long period of time, such as the deterioration of the film quality by organic solvents. Furthermore, when compared with conventionally used silicon oxide, many materials are difficult to perform fine processing using etching. Therefore, using porous bodies composed of organic materials or the mixture of organic and inorganic materials, it is difficult to fabricate semiconductor devices having a high reliability at low costs, compared with conventionally used silicon oxide.

### SUMMARY OF THE INVENTION

Therefore, an object of the present invention is to provide a semiconductor device having interlayer insulating layers that excels in chemical resistance and fine processability by using a porous body composed mainly of silicon oxide formed from inorganic materials only.

Another object of the present invention is to provide a method for manufacturing the above-described semiconductor device at low costs.

The first aspect of the semiconductor device according to the present invention is a semiconductor device comprising interlayer insulating layers formed on a substrate, and wirings formed in the interlayer insulating layers, wherein the interlayer insulating layers are composed of a porous body having fine pores of a columnar shape and a parent material region consisting mainly of silicon oxide surrounding the pores, and the wirings are composed of a structure wherein columnar substances containing aluminum dispersed in a base material composed of silicon.

The second aspect of the semiconductor device according to the present invention is a semiconductor device comprising interlayer insulating layers formed on a substrate, and wirings formed in the interlayer insulating layers, wherein the interlayer insulating layers are composed of a porous body having fine pores of a columnar shape and a parent material region consisting mainly of silicon oxide surrounding the pores, and the wirings are composed of a region wherein an electrically conducting material is introduced in a portion of the porous body.

The average pore diameter of the above-described fine pores is preferably 1 nm or larger and 15 nm or smaller; and the average distance between the pores is preferably 3 nm or longer and 20 nm or shorter. This is because the higher pore density and the smaller pore diameter make the mechanical strength of the porous body higher, and raise the reliability of the device; and the larger fine pore portion of the porous body lowers the dielectric constant and increases the speed of the device.

The above-described fine pores are preferably formed perpendicularly or substantially perpendicularly to the film surface. This is because if the fine pores are formed at a slant to the film surface, when a metallic material is inserted to form wirings, the wirings also become adversely slanted. The fine pores may be substantially perpendicular to the film surface, and is not required to be perfectly perpendicular.

By thus using silicon oxide, which has been conventionally used, as the major component, chemical resistance and the like of the film can be raised compared with organic materials. The specific dielectric constant can also be lowered by making the silicon oxide porous.

The semiconductor device according to the present invention may contain aluminum oxide in the porous body used as interlayer insulating films.

The first aspect of the method for manufacturing a semiconductor device according to the present invention has a step of preparing a structure wherein columnar substances containing aluminum as the major component are dispersed in a base material consisting mainly of silicon and containing at least aluminum; and a step of removing the columnar substances.

The second aspect of the method for manufacturing a semiconductor device according to the present invention has a step of preparing a structure wherein columnar substances containing aluminum as the major component are dispersed in a base material consisting mainly of silicon and containing at least aluminum; a removing step of removing the columnar substances; and an introducing step of introducing an electrically conductive material in a portion of the regions in the pores of the porous bodies having columnar pores formed by the removing step.

The third aspect of the method for manufacturing a semiconductor device according to the present invention has a step of preparing a structure wherein columnar substances containing aluminum as the major component are dispersed in a base material consisting mainly of silicon and containing at least aluminum; a first removing step of removing the columnar substances; a second removing step of removing a portion of the porous bodies having columnar pores formed by the first removing step; and an introducing step of introducing an electrically conductive material in porous-body-removed portions formed by the second removing step.

The step of preparing the structure is preferably a step of preparing a structure wherein the columnar substances are dispersed in the base material perpendicularly, or substantially perpendicularly to the film surface.

In such methods for manufacturing a semiconductor device, the processes of conventional wiring-burying methods, such as the removal of interlayer insulating layers, the burying of a wiring metal and planarization, can contingently omitted, and a semiconductor device using multi-layer wirings can be manufactured easily at low costs.

The history to reach the present invention will be described. The present inventors conducted research on fine structures using aluminum, and happened to reach the above-described findings.

Specifically, the present inventors found that when silicon was added during the formation of an aluminum film on a substrate using a method for forming a film of a material in a non-parallel state, such as a sputtering method, there was a case wherein aluminum of a columnar structure was spontaneously formed in the matrix of silicon substantially perpendicularly to the substrate under predetermined conditions. It was also found that when the film on which the aluminum of the columnar structure was formed was immersed in a solvent that preferentially dissolves aluminum than silicon, and oxidized, a porous body consisting mainly of silicon oxide was formed which was inorganic material wherein fine pores of a diameter of several nanometers (silicon oxide porous body) was formed.

It was also found, by the measurement of the specific dielectric constant of thus prepared silicon oxide porous body, that the specific dielectric constant lowered compared with conventional non-porous silicon oxide.

It was also possible to introduce metallic materials (including carbon nanotubes) in a porous body consisting mainly of silicon oxide (silicon oxide porous body) using an electrodeposition method, a VLS (vapor liquid solid) method or the like.

It was also found that thus prepared silicon oxide porous body had chemical resistance substantially equivalent to the chemical resistance of conventionally used silicon oxide.

Thus, the present inventors conducted repetitive studies on the bases of the above findings, and reached the present invention.

### BRIEF DESCRIPTION OF THE DRAWINGS

FIG. 1 is a schematic diagram illustrating an example of a semiconductor device of the present invention;

FIGS. 2A and 2B are schematic diagrams illustrating an example of porous bodies, which are the interlayer insulating layers of the present invention;

FIGS. 3A, 3B, 3C and 3D are process diagrams illustrating an example of a method for manufacturing a semiconductor device according to the present invention (first embodiment);

FIGS. 4A, 4B, 4C, 4D, 4E and 4F are process diagrams illustrating another example of a method for manufacturing a semiconductor device according to the present invention (second embodiment);

FIGS. 5A, 5B, 5C, 5D, 5E and 5F are process diagrams illustrating still another example of a method for manufacturing a semiconductor device according to the present invention (third embodiment);

FIGS. 6A and 6B are schematic diagrams illustrating an example of a method for manufacturing porous bodies according to the present invention; and

FIGS. 7A, 7B, 7C, 7D and 7E and are process diagrams illustrating still another example of a method for manufacturing a semiconductor device according to the present invention (fourth embodiment).

### DESCRIPTION OF THE PREFERRED EMBODIMENTS

The embodiment of a semiconductor device and a method for manufacturing the same according to the present invention will be described in detail below.

<Constitution of Semiconductor Device>

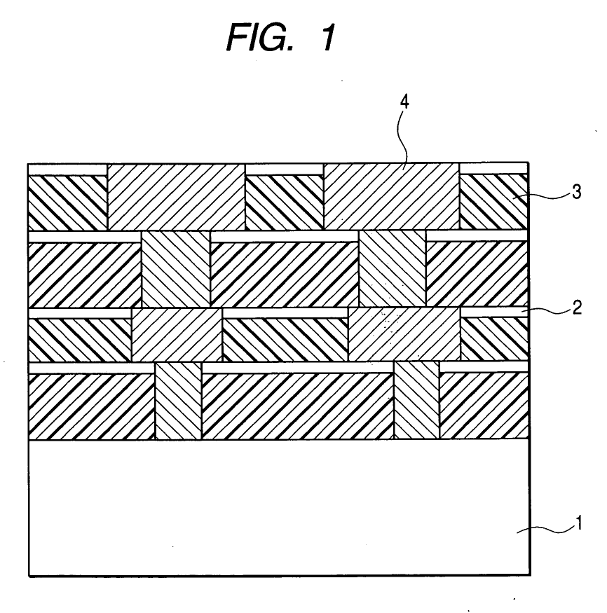

FIG. 1 is a schematic diagram illustrating an example of semiconductor devices of the present invention. FIG. 1 shows an example of semiconductor devices, wherein porous films having fine pores of a size of several to several tens of nanometers are used as interlayer insulating layers, and multi-layer wirings are formed.

In FIG. 1, the reference numeral 1 denotes a semiconductor substrate, 2 denotes protective insulating layers, 3 denotes interlayer insulating layers and 4 denotes wirings. The semiconductor device of the present invention is composed mainly of multi-layered interlayer insulating layers 3 and wirings (metal wirings) 4 formed on the semiconductor substrate 1. In FIG. 1, although barrier layers for preventing wiring metal spike and various protective layers are not shown, these may be used if there is a problem in the operation of the semiconductor device. On the semiconductor substrate 1, semiconductor elements such as MOSFET (not shown) are formed. The semiconductor device of the present invention is preferably a semiconductor device of a multi-layer wiring type composed of a plurality of interlayer insulating layers 3 and wirings 4.

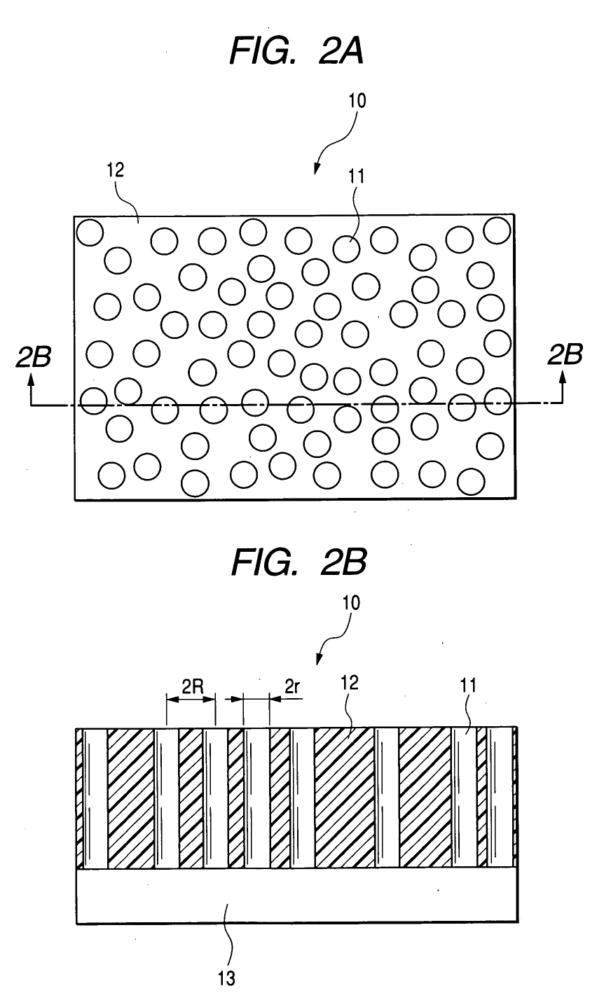

FIGS. 2A and 2B show an example of porous bodies (interlayer insulating layers) used in the semiconductor device of the present invention. FIG. 2A is a schematic diagram viewed from the film surface, and FIG. 2B is a schematic diagram viewed from the cross-section of a porous body. FIG. 2B is a schematic diagram of the cross-section cut along line 2B-2B. In FIGS. 2A and 2B, the reference numeral 10 denotes a porous body that composes an interlayer insulating layer 3, 11 denotes fine pores, 12 denotes silicon oxide and 13 denotes a semiconductor substrate.

As FIGS. 2A and 2B show, the interlayer insulating layer 3 is characterized to be composed of a porous body 10 consisting mainly of silicon oxide 12 having fine pores 11 substantially perpendicular to the semiconductor substrate 13.

As FIGS. 2A and 2B show, fine pores 11 are isolated from each other with the base material composing the porous body, and are formed substantially perpendicularly to the semiconductor substrate 13. The fine pores 11 have a columnar shape as FIG. 2B shows. The diameter of the fine pores 11 (the average diameter of the fine pores viewed from the film surface) is 1 nm or larger and 15 nm or smaller. Furthermore, the distance between the fine pores 11 is 3 nm or linger and 20 nm or shorter. The diameter of the fine pores 11 is 2r in FIG. 2B, and the distance between the fine pores 11 is 2R in FIG. 2B.

The porous body 10 is composed mainly of silicon oxide, and the composition thereof to all the elements other than oxygen is preferably 0.1 atomic % or more and 30 atomic % or less aluminum, and 70 atomic % or more and 99.9 atomic % or less silicon. Although the material of the porous body 10 preferably consists of silicon oxide, it may contain small quantities of various elements, such as argon (Ar), nitrogen (N) and hydrogen (H). Although the material of the porous body 10 is preferably porous, it may also contain crystalline materials.

In the interlayer insulating layer 3, at least a part may be composed of a porous body 10 consisting mainly of silicon oxide, and a part of the interlayer insulating layer 3 may be composed of a conventionally used low-dielectric-constant film.

The wiring 4 is characterized to be composed of a structure wherein columnar substances containing aluminum are dispersed in a base material containing silicon; to be composed of a metallic material buried in a plurality of fine pores in the interlayer insulating layer 3; or to be composed of a metallic material buried in a hole formed by a part where the interlayer insulating layer 3 has been removed. Although the metallic material composing the wiring 4 is preferably Al or Cu, which has a low resistivity and low costs, a single element metal such as Ag, Au, Mo and W, or an alloy formed by mixing two or more metals can also be used. Furthermore, CNT (carbon nanotube) may also be used.

Although the protective insulating layer 2 is preferably composed of an insulator such as SiN, it may be not used if there are no problems in the operation of the semiconductor device.

<Method for Manufacturing Semiconductor Device>

The method for manufacturing a semiconductor device according to the present invention will be described below.

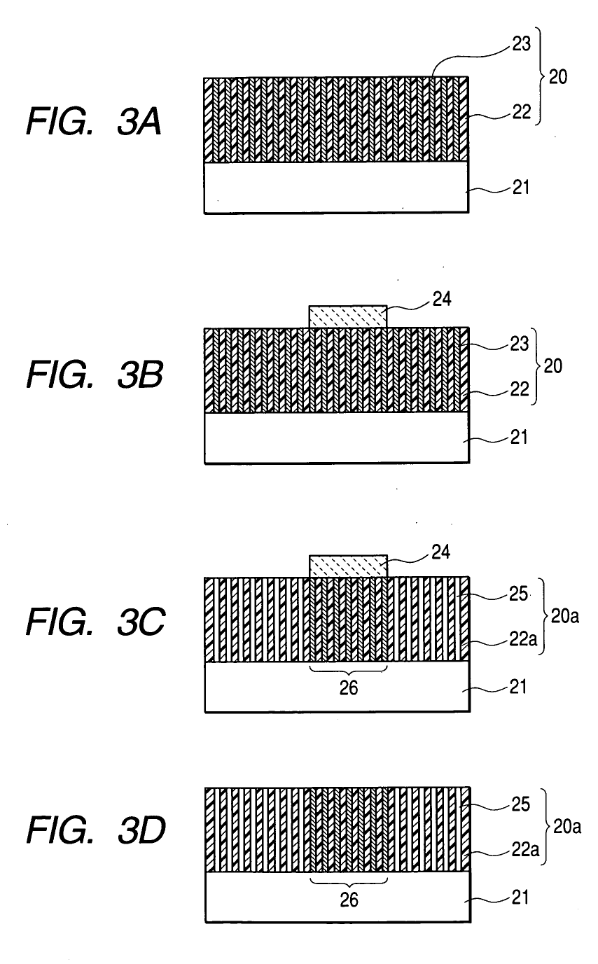

FIGS. 3A to 3D are process diagrams showing an embodiment of the method for manufacturing a semiconductor device according to the present invention. The method for manufacturing a semiconductor device according to the present invention shown in FIGS. 3A to 3D is characterized in including the following first, second and third steps.

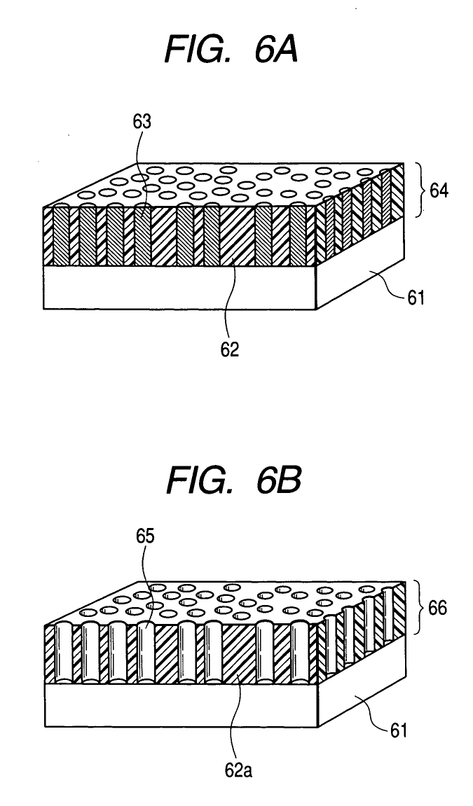

FIGS. 6A and 6B are schematic diagrams showing an example of the method for manufacturing a porous body in the semiconductor device of the present invention.

Here, the example wherein a via, which is a vertical wiring, is formed in the interlayer insulating layer will be described.

(First Step)

The first step is a step for preparing a structure wherein columnar substances consisting mainly of aluminum are dispersed in a material consisting mainly of silicon and containing at least aluminum substantially perpendicularly to the film surface.

For example, aluminum and silicon are provided, and using a method that can form a substance in a non-equilibrium state, such as a sputtering method, a structure consisting of an aluminum-silicon mixture (aluminum-silicon mixed film) 20 wherein aluminum columnar structures 23 are dispersed in a matrix of silicon 22 is formed on a semiconductor substrate 21 as FIG. 3A shows.

When the aluminum-silicon mixed film 20 is formed using such a method, as shown in FIG. 3A, aluminum and silicon form a eutectic structure in a metastable state, aluminum forms a nanostructure of a several-nanometer level (a columnar structure) in the matrix of silicon 22, and isolates by self-organization. The aluminum columnar structures 23 at this time have structures as shown in FIG. 6A. In FIG. 6A, an aluminum-silicon mixture 64 is formed on the semiconductor substrate 61, and the aluminum-silicon mixture 64 has a structure wherein aluminum columnar structures 63 are dispersed in the matrix of silicon 62.

Specifically, the aluminum columnar structures 23 shown in FIG. 3A are formed in a columnar shape substantially perpendicular to the film surface, and the pore diameter is 1 nm or larger and 15 nm or smaller and the distance between them is 3 nm or longer and 20 nm or shorter. The pore diameter and distance may be changed by adjusting the film-forming conditions and the composition of aluminum and silicon.

In the mixed film of aluminum and silicon, the quantity of silicon in the formed film is 20 to 70 atomic %, preferably 25 to 65 atomic %, and more preferably 30 to 60 atomic % to the total quantity of aluminum and silicon. If the quantity of silicon is within such a range, an aluminum-silicon mixed film 20 wherein aluminum columnar structures 23 are dispersed in the region of silicon 22 can be obtained.

The atomic percent indicating the proportion of aluminum and silicon indicates the proportion of the numbers of silicon and aluminum, and is also described as atom % or at %. For example, it is a value when the quantities of silicon and aluminum in the aluminum-silicon mixed film are quantitatively analyzed using an inductively coupled plasma emission spectrometry method (ICP method).

(Second and Third Steps)

These steps include a step for removing the aluminum columnar structures 23 (columnar substances) from the aluminum-silicon mixed film 20 (structure) after the above-described first step, and a step for oxidizing the structure after the removing step simultaneously with or after the removing step.

For example, as FIG. 3B shows, after applying a resist 24 onto the above-described aluminum-silicon mixture 20, the resist 24 is patterned using photolithography. Thereafter, as FIG. 3C shows, aluminum in the aluminum columnar structures 23 composing the columnar structures is etched from the surface of the aluminum-silicon mixed film 20 on which the resist 24 is not formed, and silicon is simultaneously oxidized to form fine pores 25 in the matrix consisting mainly of silicon oxide 22a. Thereby, silicon oxide porous body 20a and the Al wiring regions (vias) 26 are formed. The fine pores 25 in the porous body have a distance of 3 nm or longer and 20 nm or shorter, and a pore diameter of 1 nm or larger and 15 nm or smaller.

Furthermore, as FIG. 3D shows, the resist 24 is removed using a remover to complete the wirings 26 buried in the silicon oxide porous body 20a. The above-described first and second steps are repeated for several times to form the semiconductor device having multi-layer wirings shown in FIG. 1.

Although the solutions used in the etching of the aluminum columnar structures 23 include acids such as phosphoric acid, sulfuric acid, hydrochloric acid and a chromic acid solution, which dissolve aluminum but little dissolve silicon, an alkali such as sodium hydroxide can also be used if there are no adverse impacts in the formation of fine pores by etching, and the types of the acid or alkali are not specifically limited. The mixture of several kinds of acid solutions or several kinds of alkali solutions can also be used. The etching conditions, such as solution temperature, solution concentration and etching time can be suitably selected depending on the porous body to be formed.

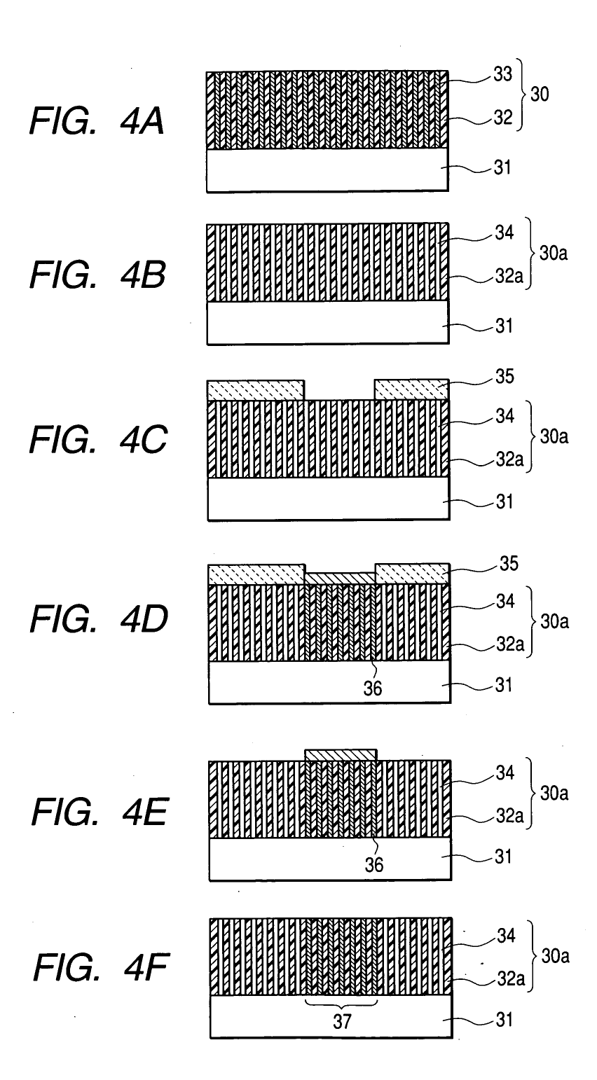

FIGS. 4A to 4F are process diagrams showing another embodiment of the method for manufacturing a semiconductor device according to the present invention. The method for manufacturing a semiconductor device according to the present invention in FIGS. 4A to 4F is characterized in having first to fourth steps described below. Here, the example wherein a via, which is a vertical wiring, is formed in the interlayer insulating layer will be described.

(First Step)

The first step is a step for preparing a structure wherein columnar substances consisting mainly of aluminum are dispersed in a material consisting mainly of silicon and containing at least aluminum substantially perpendicularly to the film surface.

For example, aluminum and silicon are provided, and using a method that can form a substance in a non-equilibrium state, such as a sputtering method, a structure wherein aluminum columnar structures 33 are dispersed in the matrix of silicon 32 on a semiconductor substrate 31, that is an aluminum-silicon mixed film 30 is formed as FIG. 4A shows.

(Second and Third Steps)

These steps consist of a removing step for removing columnar structures consisting mainly of Al, and a step for oxidizing the structures after the removing step simultaneously to or after the removing step.

For example, as FIG. 4B shows, the aluminum-silicon mixture 30 prepared as described above is immersed in a phosphoric acid solution to etch aluminum selectively, and silicon is simultaneously oxidized to form a silicon oxide porous body 30a consisting of fine pores 34 of a columnar shape and silicon oxide 32a surrounding the fine pores 34. The silicon oxide porous body 30a has a structure as FIG. 6B shows. In FIG. 6B, a silicon oxide porous body 66 is formed on a semiconductor substrate 61, and the silicon oxide porous body 66 is composed of fine pores 65 and silicon oxide 62a surrounding the fine pores 65.

Specifically, the silicon oxide porous body 30a shown in FIG. 4B has a structure that has fine pores 34 substantially perpendicular to the film surface, wherein the fine pores 34 are surrounded by a material consisting mainly of silicon oxide 32a.

(Fourth Step)

The fourth step is an introducing step for introducing an electrically conductive material in a part of regions in the fine pores 34 of the porous body 30a having the columnar fine pores 34 formed in the above removing step.

For example, as FIG. 4C shows, after forming a resist 35 on the region where the filling of a metal is not desired, as FIG. 4D shows, the fine pores 34 are filled with a wiring material (metallic material or electrically conductive material) 36 such as Cu using electrodeposition. Here, although the metallic material used for filling is typically a metallic material such as Cu and Al, which has low resistivity, the metallic material is not limited thereto, but various materials such as CNT (carbon nanotube) can also be used. Furthermore, although a method for filling the fine pores 34 with the wiring material is preferably electrodeposition, a catalytic reaction method or a VLS method can also be used.

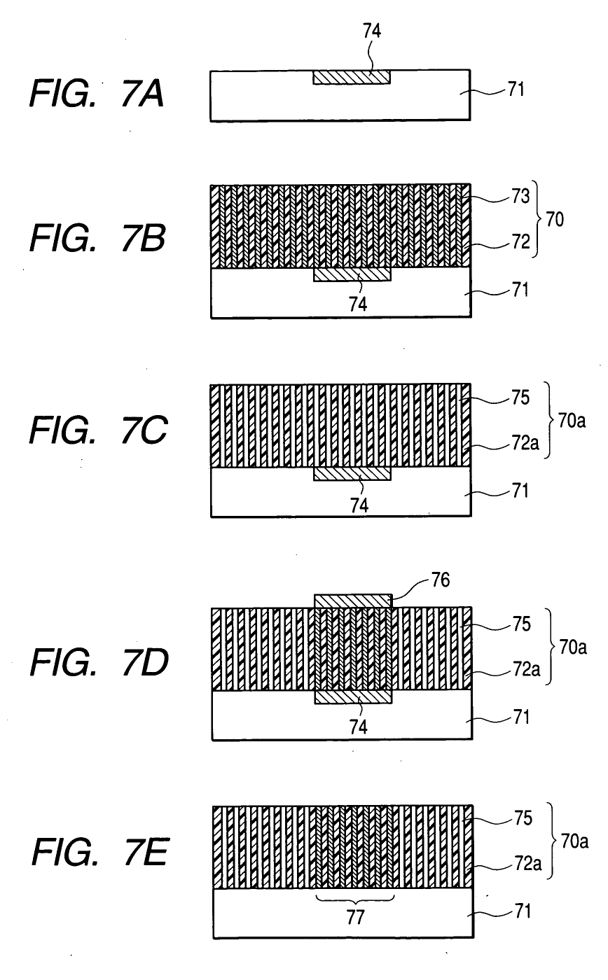

Here, although a method to electrodeposit an electrically conductive material selectively on the region other than the masked region with the resist 35 is described, a method wherein the base material in the place to be electrodeposited (wiring region) is changed, as FIGS. 7A to 7E show, and the electrically conductive material is introduced in the porous body 30a using a selective electrodeposition method for depositing the material only on a specific base material may also be adopted.

After removing the resist 35 using a remover as FIG. 4E shows, a method wherein the surface of the porous body 30a is planarized using for example, CMP (chemical-mechanical polishing) as FIG. 4E shows, to form the wiring region (via) 37, can also be used.

The first and third steps are repeated to manufacture a semiconductor device having multi-layered wirings as shown in FIG. 1.

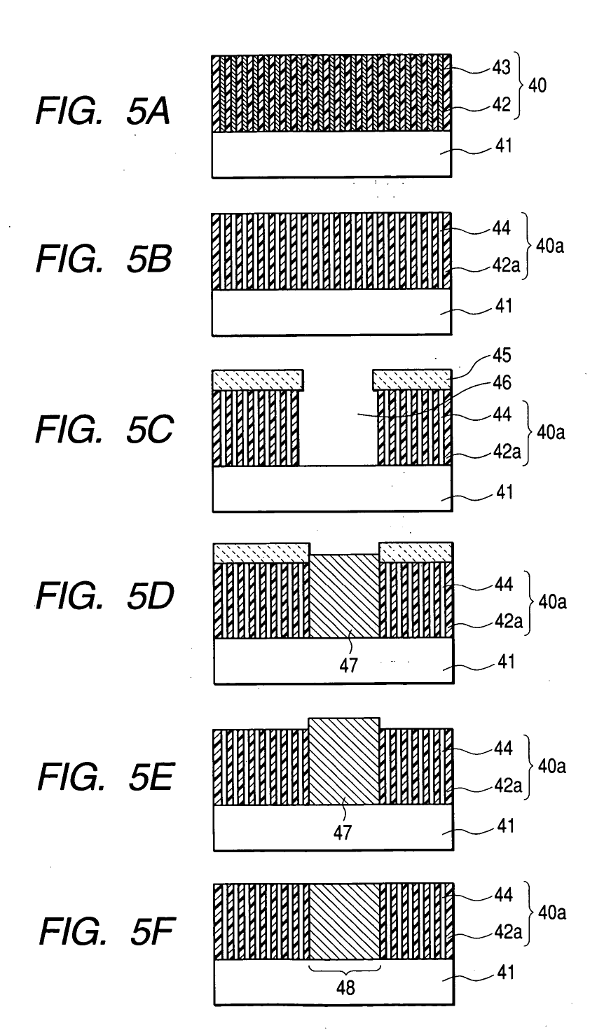

FIGS. 5A to 5F are process diagrams showing another embodiment of the method for manufacturing a semiconductor device according to the present invention. In FIGS. 5A to 5F, the method for manufacturing a semiconductor device according to the present invention is characterized in having the following first to fifth steps.

(First Step)

The first step is a step for preparing a structure wherein columnar substances consisting mainly of aluminum are dispersed in a material consisting mainly of silicon and containing at least aluminum substantially perpendicularly to the film surface.

For example, aluminum and silicon are provided, and using a method that can form a substance in a non-equilibrium state, such as a sputtering method, a structure wherein aluminum columnar structures 43 are dispersed in the matrix of silicon 42 on the semiconductor substrate 41, that is an aluminum-silicon mixed film 40 is formed as FIG. 5A shows.

(Second and Third Steps)

These steps consist of a first removing step for removing columnar structures consisting mainly of Al, and a step for oxidizing the structures after the first removing step simultaneously to or after the first removing step.

For example, as FIG. 5B shows, the aluminum-silicon mixture 40 prepared as described above is immersed in a phosphoric acid solution to etch aluminum selectively, and silicon is simultaneously oxidized to form a silicon oxide porous body 40a consisting of silicon oxide 42 surrounding the fine pores 44 on the semiconductor substrate 41.

(Fourth Step)

The fourth step is a second removing step for removing a part of the porous body 40a having columnar fine pores 44 obtained in the first removing step.

For example, as FIG. 5C shows, after forming a resist 45 on the region where the porous body 40a is not removed, the porous body 40a in the place where the resist 45 is not formed on the surface is removed using a dry etching process such as RIE, or a wet etching process.

(Fifth Step)

The fifth step is an introducing step for introducing an electrically conductive material in a region 46 after removing the porous body formed in the above second removing step.

For example, as FIG. 5D shows, the region 46 after removing the porous body 40a is filled with a wiring material (metallic material) 47 such as Cu. Furthermore, as FIG. 5E shows, after removing the resist 45 using a remover, the surface of the porous film 40a is planarized using, for example, CMP (chemical-mechanical polishing) to form a wiring region (via) 48 in the porous body 40a as FIG. 5F shows. The first to fourth steps are repeated to manufacture a semiconductor device having multi-layered wirings as shown in FIG. 1.

A semiconductor device having multi-layered wirings as shown in FIG. 1 can also be manufactured using a plurality of steps combining the first to third steps shown in FIGS. 3A to 3D, the first to fourth steps shown in FIGS. 4A to 4F, and the first to fifth steps shown in FIGS. 5A to 5F.

The present invention will be specifically described below referring to examples.

### FIRST EXAMPLE

The first example is an example of a semiconductor device wherein porous films having fine pores perpendicular to a substrate consisting mainly of silicon oxide are used as interlayer insulating layers, and wirings are formed by burying aluminum in the fine pores in the porous film. Here, an example of forming a via, which is a vertical wiring, is formed in the interlayer insulating layers will be described.

As described above, FIGS. 3A to 3D schematically show the manufacturing steps for forming interlayer insulating layers and metal wirings thereon. The manufacturing method will be described below referring to FIGS. 3A to 3D.

First, on a semiconductor substrate on which semiconductor elements such as MOSFET, wiring layers and element isolating regions (not shown) were formed, an aluminum-silicon mixture (mixed film) 20 containing 60 atomic % aluminum relative to the total quantity of aluminum and silicon as shown in FIG. 3A was formed using a magnetron sputtering method. As the target, a circular aluminum-silicon mixed target of a diameter of 4 inches (101.6 mm) fabricated by mixing silicon powder and aluminum powder in the ratio of 60 atomic % :40 atomic % was used. Sputtering was performed using an RF power source under the conditions of an Ar flow rate of 50 sccm, a discharge pressure of 0.7 Pa, and an input power of 150W. The substrate temperature was 100° C.

The aluminum-silicon mixture 20 was observed using an FE-SEM (field emission scanning electron microscope). The surface viewed from diagonally above has aluminum columnar structures arranged two-dimensionally surrounded by the silicon region as FIG. 6A shows. The pore diameter of the portion of the aluminum columnar structures was 5 nm, and the average distance between the centers of the pores was 8 nm. The FE-SEM observation of the cross-section showed that each aluminum columnar structure was independent from each other.

Next, as FIG. 3B shows, a resist 24 was formed on thus formed aluminum-silicon mixture 20. The resist 24 was removed from the portions other than the portion to form metal wirings (via-forming portion). For removing the resist 24, normal photolithography was used.

Next, the aluminum-silicon mixture on which the resist 24 was formed was immersed in a 5 wt % solution of phosphoric acid for 4 hours to remove the portion of the aluminum columnar structures 23, and the region of silicon 22 was oxidized to form fine pores 25 as shown in FIG. 3C. Thereafter, the resist 24 formed on the metal wirings was removed using a remover. As a result, a porous body 20a composed of the material consisting mainly of silicon oxide 25 was fabricated on the region other than the metal wiring (via) region 26 as FIG. 3D shows.

In such a method for forming the metal wirings (via) 26, fine pores of a diameter of up to about 5 nm substantially perpendicular to the substrate are formed only in the open portion of the resist 24, and on the region where the resist is formed the metal wirings (via) 26 are formed perpendicularly to the semiconductor substrate 21. Therefore, if the open portion of the resist 26 can be formed, the metal wirings (via) 26 of diameters up to about 5 nm can be formed. Specifically, since there is no limitation of forming the metal wiring (via) portion by fine processing of the interlayer insulating layers, this method can form finer metal wirings (via) than conventional methods.

Next, the phosphoric-acid-etched aluminum-silicon mixed film (porous body composed of a material consisting mainly of silicon oxide) 20a was observed using an FE-SEM (field emission scanning electron microscope). On the surface of the porous body 20a region other than the metal wiring (via) region 26 viewed from the diagonally above, as the silicon oxide porous body of FIG. 6B shows, fine pores surrounded by the material consisting mainly of silicon oxide were tow-dimensionally arranged. The pore diameter of the portion of the aluminum columnar structures was 5 nm, and the average distance between the centers of the pores was 8 nm. On the other hand, as FIG. 6A shows, a part of the aluminum columnar structures were left on the metal wiring (via) region. When the surface of the interlayer insulating layer was observed using an AFM, the surface was found to be very flat.

Since the fabricated porous body 20a is more porous than regular silicon oxide, it has a lowered specific dielectric constant. As a result, wiring delay can be reduced compared with a semiconductor device manufactured using regular silicon oxide. Since the porous film of the present invention is composed of an inorganic material consisting substantially of Si—O, chemical resistance is improved over a porous film composed of an organic material or the mixture of inorganic and organic materials.

Next, such steps are repeated to form a multi-layered semiconductor device as shown in FIG. 1.

Since the interlayer insulating layers of thus manufactured semiconductor device are composed of porous bodies consisting mainly of silicon oxide, the specific dielectric constant can be lowered, and the wiring capacity can be reduced.

By the use of such a manufacturing method, a metallic material can be buried in the interlayer insulating layers without performing the conventionally used wiring-metal burying process (Damascene process), including the etching of interlayer insulating layers, the plating of metallic materials, and the surface polishing by CMP; and the interlayer insulating layers having a flat surfaces can be formed. Therefore, since the number of process steps decreases, the costs of the semiconductor device can be reduced.

### SECOND EXAMPLE

The second example is an example of a semiconductor device wherein porous films having fine pores perpendicular to a substrate consisting mainly of silicon oxide are used as interlayer insulating layers, and metal wirings (via) are formed by burying Cu in the fine pores. Here, an example of forming a via, which is a vertical wiring, is formed in the interlayer insulating layers will be described.

As described above, FIGS. 4A to 4F schematically show the manufacturing steps for forming interlayer insulating layers and metal wirings thereon. The manufacturing method will be described below referring to FIGS. 4A to 4F.

First, on a semiconductor substrate 31 on which semiconductor elements such as MOSFET, wiring layers and element isolating regions (not shown) were formed, an aluminum-silicon mixture (mixed film) 30 containing 60 atomic % aluminum to the total quantity of aluminum and silicon as shown in FIG. 4A was formed using a magnetron sputtering method. As the target, a circular aluminum-silicon mixed target of a diameter of 4 inches (101.6 mm) fabricated by mixing silicon powder and aluminum powder in the ratio of 60 atomic % :40 atomic % was used. Sputtering was performed using an RF power source under the conditions of an Ar flow rate of 50 sccm, a discharge pressure of 0.7 Pa, and an input power of 150W. The substrate temperature was 100° C.

The aluminum-silicon mixture 30 was observed using an FE-SEM (field emission scanning electron microscope). The surface viewed from diagonally above has aluminum columnar structures 63 arranged two-dimensionally surrounded by the silicon region 62 as FIG. 6A shows. The pore diameter of the portion of the aluminum columnar structures was 5 nm, and the average distance between the centers of the pores was 8 nm. The FE-SEM observation of the cross-section showed that each aluminum columnar structure was independent from each other.

Next, the aluminum-silicon mixture 30 was immersed in a 5 wt % phosphoric acid solution for 4 hours to remove the portion of the aluminum columnar structures 33, and the region of silicon 32 was oxidized to form fine pores 34a. As a result, a porous body 30a composed of the material consisting mainly of silicon oxide 32a was fabricated on the entire surface of the film as FIG. 4B shows. Furthermore, in order to remove moisture in the porous body 30a, annealing was conducted at 200° C.

Next, the phosphoric-acid-etched aluminum-silicon mixed film (porous body composed of a material consisting mainly of silicon oxide) 30a was observed using an FE-SEM (field emission scanning electron microscope). On the surface viewed from the diagonally above, as the silicon oxide porous body of FIG. 6B shows, fine pores surrounded by the material consisting mainly of silicon oxide were tow-dimensionally arranged. The diameter of the pore shown in FIG. 4B was 5 nm, and the average distance between the centers of the pores was about 8 nm. When the surface of the interlayer insulating layer was observed using an AFM, the surface was found to be very flat.

Since the fabricated porous body 30a is more porous than regular silicon oxide, it has a lowered specific dielectric constant. As a result, wiring delay can be reduced compared with a semiconductor device manufactured using regular silicon oxide. Since the porous film of the present invention is composed of an inorganic material consisting substantially of Si—O, chemical resistance is improved over a porous film composed of an organic material or the mixture of inorganic and organic materials.

Next, a resist 35 was applied onto the region other than the metal wiring (via) portion of thus fabricated porous body (interlayer insulating layer) 30a as FIG. 4C shows. Here, a regular photolithography process was used to pattern the resist 35.

Next, Cu was selectively deposited in the fine pores 34 in the metal wiring (via) portion on which the resist 35 was not applied using electroplating (electrodeposition process). As a result, a structure, wherein the wiring material 36 was buried in a part of the porous body 30a, as shown in FIG. 4D, was formed. Furthermore, as FIG. 4E shows, after removing the resist 35, the interlayer insulating layer composed of the porous body 30a wherein the wiring material 36 was buried was planarized using CMP. As a result, as FIG. 4F shows, an interlayer insulating layer composed of the porous body 30a wherein Cu was buried in fine pores 34 as metal-wiring region 37 was formed.

By repeating such steps several times, a multi-layered semiconductor device as shown in FIG. 1 can be formed.

Since the interlayer insulating layers of thus manufactured semiconductor device are composed of porous bodies consisting mainly of silicon oxide, the specific dielectric constant can be lowered, and the RC delay can be prevented.

By the use of such a manufacturing method, since a metallic material is directly buried in the pores of the interlayer insulating layers, the etching process of the interlayer insulating layers can be omitted. Therefore, since the number of process steps decreases, the costs of the semiconductor device can be reduced.

Furthermore, in such a method for forming the metal wirings (via), the metal wirings (via) perpendicular to the substrate are formed only in the open portion of the resist. Therefore, since there is no limitation of forming the metal wiring (via) portion by fine processing of the interlayer insulating layers, this method can form finer metal wirings (via) than conventional methods.

### Third Example

The third example is an example of a semiconductor device wherein porous films having fine pores perpendicular to a substrate consisting mainly of silicon oxide are used as interlayer insulating layers, and Cu was buried in the region after removing a part of the porous films as metal wirings.

As described above, FIGS. 5A to 5F schematically show the manufacturing steps for forming interlayer insulating layers and metal wirings thereon. The manufacturing method will be described below referring to FIGS. 5A to 5F.

First, on a semiconductor substrate on which semiconductor elements such as MOSFET, wiring layers and element isolating regions (not shown) were formed, an aluminum-silicon mixture (mixed film) 40 containing 60 atomic % aluminum to the total quantity of aluminum and silicon as shown in FIG. 5A was formed using a magnetron sputtering method. As the target, a circular aluminum-silicon mixed target of a diameter of 4 inches (101.6 mm) fabricated by mixing silicon powder and aluminum powder in the ratio of 60 atomic % :40 atomic % was used. Sputtering was performed using an RF power source under the conditions of an Ar flow rate of 50 sccm, a discharge pressure of 0.7 Pa, and an input power of 150W. The substrate temperature was 100° C.

The aluminum-silicon mixture 40 was observed using an FE-SEM (field emission scanning electron microscope). The surface viewed from diagonally above has aluminum columnar structures arranged two-dimensionally surrounded by the silicon region as FIG. 6A shows. The pore diameter of the portion of the aluminum columnar structures was 5 nm, and the distance between the centers of the pores was 8 nm. The FE-SEM observation of the cross-section showed that each aluminum columnar structure was independent from each other.

Next, the aluminum-silicon mixture 30 was immersed in a 5 wt % phosphoric acid solution for 4 hours to remove the portion of the aluminum columnar structures 33, and the region of silicon 42 was oxidized to form fine pores 44. As a result, a porous body 40a composed of the material consisting mainly of silicon oxide 42a was fabricated on the entire surface of the film as FIG. 5B shows. Furthermore, in order to remove moisture in the porous body 40a, annealing was conducted at 200° C.

Next, the phosphoric-acid-etched aluminum-silicon mixed film (porous body composed of a material consisting mainly of silicon oxide) 40a was observed using an FE-SEM (field emission scanning electron microscope). On the surface viewed from the diagonally above, as the silicon oxide porous body of FIG. 6B shows, fine pores surrounded by the material consisting mainly of silicon oxide were tow-dimensionally arranged. The diameter of the pore was 5 nm, and the average distance between the centers of the pores was about 8 nm. When the surface of the interlayer insulating layer was observed using an AFM, the surface was found to be very flat. Here, although an insulating film such as an SiN film may be formed on the porous body as a protective layer, the case without using the protective layer is shown in this example.

Since the fabricated porous body 40a is more porous than regular silicon oxide, it has a lowered specific dielectric constant. As a result, wiring delay can be reduced compared with a semiconductor device manufactured using regular silicon oxide. Since the porous film of the present invention is composed of an inorganic material consisting substantially of Si—O, chemical resistance is improved over a porous film composed of an organic material or the mixture of inorganic and organic materials.

Next, a resist 45 was applied onto the region other than the metal wiring portion of thus fabricated porous body (interlayer insulating layer) 40a. Here, a regular photolithography process was used to pattern the resist 45. Furthermore, the interlayer insulating layer was etched using dry etching to form a wiring-burying region. As a result, as FIG. 5C shows, a structure wherein a porous-body-removed region 46 was formed as the wiring-burying region in a part of the porous body 40a was obtained. Since the formed porous body 40a was composed mainly of inorganic silicon oxide, it can be etched under the same conditions as the conditions for etching ordinary silicon oxide. Therefore, fine processing as substantially the same degree as the processing of ordinary silicon oxide can be performed.

Next, Cu was selectively deposited as the wiring material (metallic material) 47 on the porous-body-removed region 46, which was a wiring-burying region, and as FIG. 5D shows, to form a structure wherein the wiring material 47 was buried in the porous-body-removed region 46. Furthermore, as FIG. 5E shows, after removing the resist 45, the interlayer insulating layer composed of the porous body 40a wherein the wiring material 47 was buried was planarized using a CMP method. As a result, as FIG. 5F shows, a structure wherein Cu, which was buried to form a wiring metal, was formed as the wiring region (via) 48 in the porous body 40a composing the interlayer insulating layer.

By repeating such steps several times, a multi-layered semiconductor device as shown in FIG. 1 can be formed.

Since the interlayer insulating layers of thus manufactured semiconductor device are composed of porous bodies consisting mainly of silicon oxide, the specific dielectric constant can be lowered, and the RC delay can be prevented.

The multi-layered semiconductor device as shown in FIG. 1 can also be formed using a plurality of interlayer insulating layers wherein the metal wirings obtained in each example are buried. Thereby, various wiring structures can be formed as required in a semiconductor device.

### Fourth Example

The fourth example is an example of a semiconductor device wherein porous films having fine pores perpendicular to a substrate consisting mainly of silicon oxide are used as interlayer insulating layers, and Cu was buried as metal wirings (via) in the fine pores. Here, an example wherein the via, which are vertical wirings, are formed in the interlayer insulating layer will be described.

As described above, FIGS. 7A to 7E schematically show the manufacturing steps for forming interlayer insulating layers and metal wirings (via) thereon. The manufacturing method will be described below referring to FIGS. 7A to 7E.

First, as FIG. 7A shows, on a region to form wirings (via) on the semiconductor substrate 71 on which semiconductor elements such as MOSFET, wiring layers and element isolating regions (not shown) were formed, Pd of a thickness of 30 nm for selectively electrodepositing an electrically conductive material was formed as the base layer 74 of the wiring region. For patterning Pd, ordinary lithography was used.

Next, aluminum-silicon mixture (mixed film) 70 containing 60 atomic % aluminum to the total quantity of aluminum and silicon, as shown in FIG. 7B, was formed using a magnetron sputtering method on a semiconductor substrate 71 where the base layer 74 of the wiring region was fabricated. As the target, a circular aluminum-silicon mixed target of a diameter of 4 inches (101.6 mm) fabricated by mixing silicon powder and aluminum powder in the ratio of 60 atomic % :40 atomic % was used. Sputtering was performed using an RF power source under the conditions of an Ar flow rate of 50 sccm, a discharge pressure of 0.7 Pa, and an input power of 150W. The substrate temperature was 100° C.

The aluminum-silicon mixed film 70 was observed using an FE-SEM (field emission scanning electron microscope). The surface viewed from diagonally above has aluminum columnar structures arranged two-dimensionally surrounded by the silicon region as FIG. 6A shows. The pore diameter of the portion of the aluminum columnar structures was 5 nm, and the average distance between the centers of the pores was 8 nm. The FE-SEM observation of the cross-section showed that each aluminum columnar structure was independent from each other.

Next, the aluminum-silicon mixed film 70 was immersed in a 5 wt % phosphoric acid solution for 4 hours to remove the portion of the aluminum columnar structures 73, and the region of silicon 72 was oxidized to form fine pores 75. As a result, a porous body 70a composed of the material consisting mainly of silicon oxide 72a was fabricated on the entire surface of the film as FIG. 7C shows. Furthermore, in order to remove moisture in the porous body 70a, annealing was conducted at 200° C.

Next, the phosphoric-acid-etched aluminum-silicon mixed film (porous body composed of a material consisting mainly of silicon oxide) 70a was observed using an FE-SEM (field emission scanning electron microscope). On the surface viewed from the diagonally above, as the silicon oxide porous body of FIG. 6B shows, fine pores surrounded by the material consisting mainly of silicon oxide were tow-dimensionally arranged. The diameter of the pore was 5 nm, and the average distance between the centers of the pores was about 8 nm. When the surface of the interlayer insulating layer was observed using an AFM, the surface was found to be very flat.

Since the fabricated porous body 70a is more porous than regular silicon oxide, it has a lowered specific dielectric constant. As a result, wiring delay can be reduced compared with a semiconductor device manufactured using regular silicon oxide. Since the porous film of the present invention is composed of an inorganic material consisting substantially of Si—O, chemical resistance is improved over a porous film composed of an organic material or the mixture of inorganic and organic materials.

Next, Cu was selectively deposited as the wiring material (metallic material) 76 in the pores in which Pd was formed using electroless plating. As a result, as FIG. 7D shows, a structure wherein the wiring metal 76 was buried in a part of the porous body 70a was formed. Furthermore, the surface of the porous body 70a, which was the interlayer insulation layer wherein the wiring metal 76 was buried, was planarized using a CMP method. As a result, as FIG. 7E shows, an interlayer insulating layer composed of Cu-buried porous body 70a was formed as the metal wiring region (via) in the porous body 77 in a part of fine pores 75.

By repeating such steps several times, a multi-layered semiconductor device as shown in FIG. 1 can be formed.

Since the interlayer insulating layers of thus manufactured semiconductor device are composed of porous bodies consisting mainly of silicon oxide, the specific dielectric constant can be lowered, and the RC delay can be prevented.

By the use of such a manufacturing method, since a metallic material is directly buried in the pores of the interlayer insulating layers, the etching process of the interlayer insulating layers can be omitted. Therefore, since the number of process steps decreases, the costs of the semiconductor device can be reduced.

Furthermore, in such a method for forming the metal wirings (via), the metal wirings (via) perpendicular to the substrate are formed only in the open portion of the resist. Therefore, since there is no limitation of forming the metal wiring (via) portion by fine processing of the interlayer insulating layers, this method can form finer metal wirings (via) than conventional methods.

The multi-layered semiconductor device as shown in FIG. 1 can also be formed using a plurality of interlayer insulating layers wherein the metal wirings obtained in each example are buried. Thereby, various wiring structures can be formed as required in a semiconductor device.

Next, preliminary experiments on the structure consisting of aluminum-silicon mixture 20, 30, 40, 64 and 70 used in the present invention will be described. The structure include a matrix portion consisting mainly of Al as a first material, and Si as a second material.

### Experiment Example 1

### First Material Al, Second Material Si

An Al thin wire wherein the Al structural portion surrounded by Si is a columnar structure having a diameter 2r of 3 nm, a distance 2R of 7 nm and a length L is 200 nm (refer to columnar aluminum portion 21 in FIG. 2) will be described.

First, a method for fabricating the Al thin wire will be described.

An Al—Si mixed film containing 55 atomic % Si to the total quantity of Al and Si, of a thickness of about 200 nm, was formed on a glass substrate using an RF magnetron sputtering method. As the target, a 4-inch Al target, on which eight 15-mm-square Si chips 13 was placed, was used. Sputtering was performed using an RF power source under conditions of an Ar flow rate of 50 sccm, a charge pressure of 0.7 Pa, and an input power of 1 kW. The substrate temperature was a room temperature.

Here, although an Al target, on which eight 15-mm-square Si chips 13 were placed, was used as the target, the number of Si chips is lot limited thereto, but can be changed depending on the conditions of sputtering as long as the content of Si in the AlSi mixed film is nearly 55 atomic %. The target is not limited to an Al target on which Si chips are placed, but may be an Si target on which Al chips are placed, or may be a target formed by sintering Si and Al powders.

Next, the content (atomic %) of Si to the total quantity of Al and Si in thus obtained Al—Si mixed film was analyzed using ICP (inductively coupled plasma emission spectrometry). As a result, the content of Si to the total quantity of Al and Si was about 55 atomic %. Here, for the convenience of measurement, an Al—Si mixed film deposited on a carbon substrate as the substrate was used.

The Al—Si mixed film was observed using an FE-SEM. On the surface viewed from immediately above the substrate, circular Al nanostructures surrounded by Si were two-dimensionally arranged. The pore diameter in the Al nanostructure portion was 3 nm, and the average distance between the centers thereof was 7 nm. When the cross-section was observed using an FE-SEM, the height was 200 nm, and each Al nanostructure portion was independent from each other.

When the sample was observed using X-ray diffraction, no Si peak indicating crystallinity was found, proving that the Si was amorphous.

Therefore, Al—Si nanostructure including Al thin wires of a distance 2R of 7 nm, a diameter 2r of 3 nm and a height L of 200 nm surrounded by Si could be fabricated.

### COMPARATIVE EXAMPLES

As Comparative Sample A, an Al—Si mixed film containing 15 atomic % Si to the total quantity of Al and Si of a thickness of about 200 nm was formed on a glass substrate using a sputtering method. As the target, a 4-inch Al target, on which two 15-mm-square Si chips 13 was placed, was used. Sputtering was performed using an RF power source under conditions of an Ar flow rate of 50 sccm, a charge pressure of 0.7 Pa, and an input power of 1 kW. The substrate temperature was a room temperature.

Comparative Sample A was observed using an FE-SEM. On the surface viewed from immediately above the substrate, the Al portions were not circular, but rope-shaped. In other words, the fine structure wherein Al columnar structures were evenly dispersed in the Si region could not be formed. Furthermore, the size thereof far exceeded 10 nm. When the cross-section was observed using an FE-SEM, the width of the Al portion exceeded 15 nm. The content (atomic %) of Si to the total quantity of Al and Si in thus obtained Al—Si mixed film was analyzed using ICP (inductively coupled plasma emission spectrometry). As a result, the content of Si to the total quantity of Al and Si was about 15 atomic %.

As Comparative Sample B, an Al—Si mixed film containing 75 atomic % Si to the total quantity of Al and Si of a thickness of about 200 nm was formed on a glass substrate using a sputtering method. As the target, a 4-inch Al target, on which fourteen 15-mm-square Si chips 13 was placed, was used. Sputtering was performed using an RF power source under conditions of an Ar flow rate of 50 sccm, a charge pressure of 0.7 Pa, and an input power of 1 kW. The substrate temperature was a room temperature.

Comparative Sample B was observed using an FE-SEM. On the surface viewed from immediately above the substrate, no Al portions were observed. On the cross-section observed using an FE-SEM, the Al portions were not clearly observed. The content (atomic %) of Si to the total quantity of Al and Si in thus obtained Al—Si mixed film was analyzed using ICP (inductively coupled plasma emission spectrometry). As a result, the content of Si to the total quantity of Al and Si was about 75 atomic %.

Only the number of Si chips was changed from the case when Comparative Sample A was fabricated to prepare the samples containing 20 atomic %, 35 atomic %, 50 .atomic %, 60 atomic % and 70 atomic %. The nanostructures wherein Al columnar structures are evenly dispersed are indicated with o and the nanostructures wherein Al columnar structures are evenly dispersed are indicated with x in the following Table 1.

TABLE 1

| Silicon content (atomic %) | Nanostructure |
|---|---|
| 15 (Comparative Sample A) | x |
| 20 | o |
| 25 | o |
| 35 | o |
| 50 | o |
| 55 | o |
| 60 | o |
| 65 | o |
| 70 | o |
| 75 (Comparative Sample B) | x |

By thus adjusting the Si content to the total quantity of Al and Si to 20 atomic % or more and 70 atomic % or less, the pore diameter of the fabricated Al nanostructures can be controlled, and the Al thin wires of an excellent linearity can be fabricated. For the evaluation of the structures, the use of a TEM (transmission electron microscope) or the like in addition to an SEM is recommendable. Furthermore, as Comparative Sample C, an Al—Si mixed film containing 55 atomic % Si to the total quantity of Al and Si of a thickness of about 200 nm was formed on a glass substrate using a sputtering method. As the target, a 4-inch Al target, on which eight 15-mm-square Si chips 13 was placed, was used. Sputtering was performed using an RF power source under conditions of an Ar flow rate of 50 sccm, a charge pressure of 0.7 Pa, and an input power of 1 kW. The substrate temperature was 250° C.

Comparative Sample C was observed using an FE-SEM. On the surface viewed from immediately above the substrate, no clear boundary between Al and Si was observed. In other words, no Al nanostructures were found. Specifically, if the substrate temperature was excessively high, it is considered that the film for forming such Al nanostructures cannot be grown, because the sample is changed to a more stable state.

In order to obtain the structure wherein columnar materials are dispersed, it is also preferable to set the composition of the target to Al:Si=55:45 or the like.

As described above, when the columnar substances consisting mainly of aluminum are removed from a structure wherein the columnar substances consisting mainly of aluminum is dispersed substantially perpendicularly to the film surface in a base material consisting mainly of silicon and containing at least aluminum, and further the base material consisting mainly of silicon is oxidized, a porous body having fine pores substantially perpendicular to the substrate consisting substantially of silicon oxide can be formed; and by use of porous body as the interlayer insulating layer, a semiconductor device having a reduced wiring capacity can be formed.

The present invention can also provide a method for easily manufacturing the above-described semiconductor device.

What is claimed is:

1. A semiconductor device comprising:
a substrate,
interlayer insulating layers disposed on the substrate, and
wirings disposed in the interlayer insulating layers, wherein
the interlayer insulating layers are porous bodies comprising silicon oxides as the major component having columnar pores, and
the wirings comprise columnar portions containing aluminum, and portions containing silicon and surrounding the columnar portions.

2. A semiconductor device comprising interlayer insulating layers formed on a substrate, and wirings formed in the interlayer insulating layers, wherein
the interlayer insulating layers are composed of porous bodies comprising fine columnar pores and parent-material regions comprising silicon oxides as the major component the fine pores; and
the wirings are composed of regions wherein an electrically conductive material is introduced in a portion of the porous bodies.

3. The semiconductor device according to claim 1, wherein the average pore diameter of the pores is 1 nm or larger and 15 nm or smaller, and the average distance between the pores is 3 nm or larger and 20 nm or smaller.

4. The semiconductor device according to claim 1, wherein the pores are formed perpendicularly, or substantially perpendicularly to the surface of the substrate.

5. The semiconductor device according to claim 2, wherein the electrically conductive material is Cu.

6. A method for manufacturing a semiconductor device comprising:
a step of preparing a structure wherein columnar substances containing aluminum as the major component are dispersed in a base material consisting mainly of silicon and containing at least aluminum;
a removing step of removing a portion of the columnar substances; and
a step of oxidizing the structure after the removing step, simultaneously to or after the removing step.

7. A method for manufacturing a semiconductor device comprising:
a step of preparing a structure wherein columnar substances containing aluminum as the major component are dispersed in a base material consisting mainly of silicon and containing at least aluminum;
a removing step of removing the columnar substances;
a step of oxidizing the structure after the removing step, simultaneously to or after the removing step; and
an introducing step of introducing an electrically conductive material in a portion of the regions in the pores of the porous bodies having columnar pores formed by the removing step.

8. A method for manufacturing a semiconductor device comprising:
a step of preparing a structure wherein columnar substances containing aluminum as the major component are dispersed in a base material consisting mainly of silicon and containing at least aluminum;
a first removing step of removing the columnar substances;
a step of oxidizing the structure after the first removing step, simultaneously to or after the first removing step;
a second removing step of removing a portion of the porous bodies having columnar pores formed by the first removing step; and
an introducing step of introducing an electrically conductive material in porous-body-removed portions formed by the second removing step.

9. The method for manufacturing a semiconductor device according to claim 7, wherein the step of preparing the structure is a step of preparing a structure wherein the columnar substances are dispersed in the base material perpendicularly, or substantially perpendicularly to the film surface.
